(19) United States
(12) Patent Application Publication
(10) Pub. No.: US 2026/0004827 A1
(43) Pub. Date: Jan. 1, 2026

(54) SEMICONDUCTOR DEVICE, SEMICONDUCTOR SYSTEM, AND OPERATING METHOD OF A SEMICONDUCTOR SYSTEM

(71) Applicant: SK hynix Inc., Icheon-si Gyeonggi-do (KR)

(72) Inventors: Jae Hyeong HONG, Icheon-si Gyeonggi-do (KR); Ji Hye BAE, Icheon-si Gyeonggi-do (KR); Keun Seon AHN, Icheon-si Gyeonggi-do (KR); Soon Sung AN, Icheon-si Gyeonggi-do (KR); Sung Hwa OK, Icheon-si Gyeonggi-do (KR); Eun Ji CHOI, Icheon-si Gyeonggi-do (KR)

(73) Assignee: SK hynix Inc., Icheon-si Gyeonggi-do (KR)

(21) Appl. No.: 19/035,341

(22) Filed: Jan. 23, 2025

Related U.S. Application Data
(60) Provisional application No. 63/664,435, filed on Jun. 26, 2024.

(30) Foreign Application Priority Data
Oct. 21, 2024 (KR) 10-2024-0144334

(51) Int. Cl. G11C 7/10; G11C 7/22; G11C 29/52

(52) U.S. Cl. CPC G11C 7/1093; G11C 7/222; G11C 29/52

(57) ABSTRACT

A semiconductor device includes a receiving circuit, an oscillator code generation circuit, and a control circuit. The receiving circuit receives a clock signal and a data signal including data, delays the clock signal by a clock delay time to generate an internal clock signal, and captures the data using the internal clock signal. The oscillator code generation circuit generates an oscillation signal having a period of N times the clock delay time, wherein N is a positive integer, and generates an oscillator code based on the oscillation signal. The control circuit controls the oscillator code generation circuit in response to at least one external signal, during an initialization stage after power-on.

### CROSS-REFERENCES TO RELATED APPLICATION

The present application claims the benefit of U.S. Provisional Application No. 63/664,435 filed on Jun. 26, 2024 and claims priority under 35 U.S.C. § 119(a) to Korean Application No. 10-2024-0144334 filed on Oct. 21, 2024, in the Korean Intellectual Property Office, which applications are incorporated herein by reference in their entirety.

### BACKGROUND

### 1.Technical Field

Various embodiments generally relate to a semiconductor device and, more particularly, to a semiconductor system including the semiconductor device and a method of operating the semiconductor system.

### 2. Related Art

Semiconductor devices are important components in computers or electronic equipment and can operate based on a clock signal. Data is transmitted to a semiconductor device in synchronization with a clock signal, and the semiconductor device can process the data based on the timing of the clock signal.

The timing of the clock signal may change due to changes in voltage and/or temperature. Jitter in the clock signal may cause the semiconductor device to process data incorrectly, resulting in data loss or system failure. Therefore, to maximize the performance of a semiconductor system and maintain data integrity, measures may be taken to efficiently and accurately adjust timing of a clock signal.

### SUMMARY

In an embodiment, a semiconductor device may include a receiving circuit, an oscillator code generation circuit, and a control circuit. The receiving circuit may be configured to receive a clock signal and a data signal including data, may be configured to delay the clock signal by a clock delay time to generate an internal clock signal, and may be configured to capture the data using the internal clock signal. The oscillator code generation circuit may be configured to generate an oscillation signal having a period of N times the clock delay time, wherein N is a positive integer, and may be configured to generate an oscillator code based on the oscillation signal. The control circuit may be configured to control the oscillator code generation circuit in response to at least one external signal, during an initialization stage after power-on.

In an embodiment, a semiconductor system may include a semiconductor device and a controller. The semiconductor device may be configured to process a clock signal and data based on a clock delay time. The controller may be configured, in during initialization stage after power-on, to determine a clock-data time corresponding to the clock delay time by a training operation on the clock signal and the data, and may be configured to obtain a first oscillator code by controlling the semiconductor device to perform a first oscillator operation. The semiconductor device may be configured to, in the first oscillator operation, generate an oscillation signal having a period of N times the clock delay time, wherein N is a positive integer, and may be configured to generate the first oscillator code based on the oscillation signal.

In an embodiment, an operating method of a semiconductor system may include: determining, by a controller, a clock-data time corresponding to a clock delay time of a semiconductor device through a training operation; obtaining, by the controller, a first oscillator code by controlling the semiconductor device to perform a first oscillator operation; obtaining, by the controller, a second oscillator code by controlling the semiconductor device to perform a second oscillator operation; and adjusting, by the controller, the clock-data time based on a difference between the first oscillator code and the second oscillator code.

### BRIEF DESCRIPTION OF THE DRAWINGS

FIG. 1 is a block diagram illustrating a semiconductor system according to an embodiment of the present disclosure.

FIG. 2 is a block diagram illustrating a receiving circuit of a semiconductor device according to an embodiment of the present disclosure.

FIGS. 3 and 4 are timing diagrams to illustrate an operation of a receiving circuit according to an embodiment of the present disclosure.

FIG. 5 is a diagram illustrating a case where a change in voltage causes a change in a clock delay time in a clock path circuit, according to an embodiment of the present disclosure.

FIG. 6 is a diagram illustrating a case where a change in internal temperature causes a change in a clock delay time in a clock path circuit, according to an embodiment of the present disclosure.

FIG. 7 is a block diagram illustrating an oscillator code generation circuit of a semiconductor device according to an embodiment of the present disclosure.

FIG. 8 is a block diagram illustrating a control circuit according to an embodiment of the present disclosure.

FIG. 9 is a timing diagram to illustrate how a semiconductor device performs an oscillator operation according to an embodiment of the present disclosure.

FIG. 10 is a flowchart illustrating an operating method of a semiconductor system according to an embodiment of the present disclosure.

### DETAILED DESCRIPTION

Hereinafter, embodiments of the present disclosure will be described in more detail with reference to the accompanying drawings.

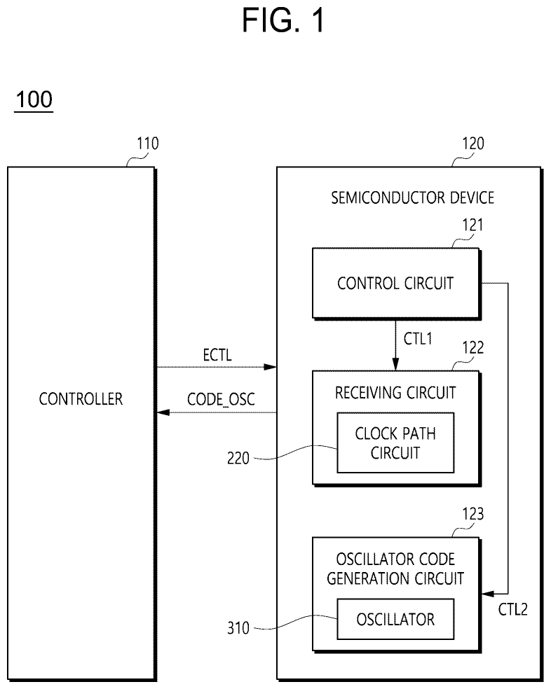

FIG. 1 is a block diagram illustrating a semiconductor system 100 according to an embodiment of the present disclosure.

Referring to FIG. 1, the semiconductor system 100 may include a controller 110 and a semiconductor device 120.

The controller 110 may control the semiconductor device 120 by transmitting at least one external signal ECTL to the semiconductor device 120. The at least one external signal ECTL may include a data signal, a clock signal, a command latch enable signal, an address latch enable signal, and a write enable signal. The data signal may include a command, an address, and data. The clock signal may be a signal that provides timing for the semiconductor device 120 to capture data from the data signal. The command latch enable signal may be a signal for the semiconductor device 120 to use to identify a command from the data signal. The address latch enable signal may be a signal for the semiconductor device 120 to use to identify an address from the data signal. The write enable signal may be a signal that provides timing for the semiconductor device 120 to capture a command and an address from the data signal.

The semiconductor device 120 may include a control circuit 121, a receiving circuit 122, and an oscillator code generation circuit 123.

The control circuit 121 may control an operation of the semiconductor device 120 in response to the at least one external signal ECTL. The control circuit 121 may control the receiving circuit 122 through at least one first internal signal CTL1 and may control the oscillator code generation circuit 123 through at least one second internal signal CTL2.

The receiving circuit 122 may receive a clock signal and data included in the at least one external signal ECTL, delay the clock signal by a clock delay time to generate an internal clock signal, and capture data with the internal clock signal. The receiving circuit 122 may include a clock path circuit 220. The clock path circuit 220 may delay the clock signal by the clock delay time to output the internal clock signal.

The oscillator code generation circuit 123 may generate an oscillation signal having a period of N times the clock delay time (where N is a positive integer) and perform an oscillator operation to generate an oscillator code based on the oscillation signal. The oscillator code generation circuit 123 may count the oscillation signal and generate a count value as the oscillator code. The oscillator code generation circuit 123 may include an oscillator 310. The oscillator 310 may mimic the clock path circuit 220, which delays the clock signal by the clock delay time, and may output the oscillation signal with a period of N times the clock delay time. In an embodiment, a cycle period of the oscillator may be substantially equal to the clock delay time of the clock path circuit 220.

The oscillator code may be generated to reflect the clock delay time of the clock path circuit 220 at the time an oscillator operation is performed. When the clock delay time of the clock path circuit 220 changes due to changes in voltage and/or temperature, the period of the oscillation signal may also change, and thus, the oscillator code may also change.

The controller 110 may perform a training operation on the semiconductor device 120 during an initialization stage after power-on. The training operation may be performed to optimize various signal timings. The training operation may include determining a clock-data time for a clock signal and data. The clock-data time may be a delay time between the clock signal and the data. The clock-data time may be the time at which the clock signal is transmitted before a midpoint of a valid window of the data. The clock-data time may be determined as the clock delay time of the clock path circuit 220 at the time the training operation is performed.

The training operation may be performed by repeating a test write operation and a test read operation a plurality of times to determine the clock-data time. After the clock-data time is determined by the training operation, the controller 110 may transmit a clock signal that precedes the midpoint of the valid window of data by the clock-data time. The clock signal may be delayed by the clock delay time as the internal clock signal in the clock path circuit 220, and the internal clock signal may be aligned with the midpoint of the valid window of data.

In an embodiment, the training operation may also be performed after the initialization stage. However, because the training operation requires repeating the test write operation and the test read operation a plurality of times, excessive training operations may cause performance degradation of the semiconductor system 100. Therefore, the controller 110 may obtain an initial oscillator code (or, a first oscillator code) during the initialization stage to minimize or omit training operations after the initialization stage.

Specifically, the controller 110 may obtain the initial oscillator code by controlling the semiconductor device 120 to perform an initial oscillator operation (or, a first oscillator operation) based on the at least one external signal ECTL during the initialization stage. The initial oscillator operation and the initial oscillator code may be an oscillator operation performed during the initialization stage and an oscillator code obtained therefrom. The controller 110 may maintain the initial oscillator code in a separate memory (not shown).

The controller 110 may control the semiconductor device 120 to transmit the initial oscillator code determined by the initial oscillator operation to the controller 110 after the initial oscillator operation of the semiconductor device 120 ends. The controller 110 may transmit a separate code transmission command to the semiconductor device 120 instructing the transmission of the initial oscillator code after the initial oscillator operation ends, and the semiconductor device 120 may transmit the initial oscillator code to the controller 110 in response to the code transmission command. In an embodiment, the semiconductor device 120 may transmit the initial oscillator code to the controller 110 in response to the initial oscillator operation, even in the absence of the code transmission command.

After the initialization stage, the controller 110 may determine whether the clock-data time needs to be adjusted. For example, changes in voltage and/or temperature may change the clock delay time of the clock path circuit 220, thereby causing a timing error in the receiving circuit 122. When the controller 110 determines that a timing error has occurred, the controller 110 may determine that the clock-data time needs to be adjusted in response to the changed clock delay time. In an embodiment, the controller 110 may determine that the clock-data time needs to be adjusted based on a predetermined period. The word “predetermined” as used herein with respect to a parameter, such as a predetermined timing, time, conversion algorithm, preamble, edges, interval code, level, or voltage level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm. In an embodiment, the controller 110 may determine that the clock-data time needs to be adjusted in response to a request from the semiconductor device 120.

In response to the determination that the clock-data time needs to be adjusted, the controller 110 may obtain a new oscillator code (or, a second oscillator code) by controlling the semiconductor device 120 to perform an additional oscillator operation (or, a second oscillator operation). A difference between the initial oscillator code and the new oscillator code may correspond to a change in the amount of the clock delay time in the clock path circuit 220. Thus, the controller 110 may adjust the clock-data time determined in the initialization stage based on the difference between the initial oscillator code and the new oscillator code. For example, the controller 110 may apply a predetermined conversion algorithm to the difference between the initial oscillator code and the new oscillator code to determine the amount of adjustment to the clock-data time. The conversion algorithm may be predetermined by testing during a manufacturing stage.

In summary, because the controller 110 already has the initial oscillator code, the controller 110 may further acquire the new oscillator code with a new oscillator operation after the initialization stage to efficiently adjust the clock-data time and maintain the performance of the semiconductor system 100. Because the controller 110 does not need to perform the training operation again after the initialization stage to adjust the clock-data time, timing correction can be performed efficiently and quickly when a timing error occurs.

The semiconductor device 120 may include one or more semiconductor chips and one or more semiconductor dies.

The semiconductor device 120 may include a non-volatile memory device and/or a volatile memory device. The non-volatile memory device may include NAND Flash Memory, 3D NAND Flash Memory, NOR Flash memory, Resistive Random Access Memory (RRAM), Phase-Change Memory (PRAM), Magnetoresistive Random Access Memory (MRAM), Ferroelectric Random Access Memory (FRAM), and Spin Transfer Torque Random Access Memory (STT-RAM). The volatile memory device may include Dynamic Random Access Memory (DRAM) and Static Random Access Memory (SRAM).

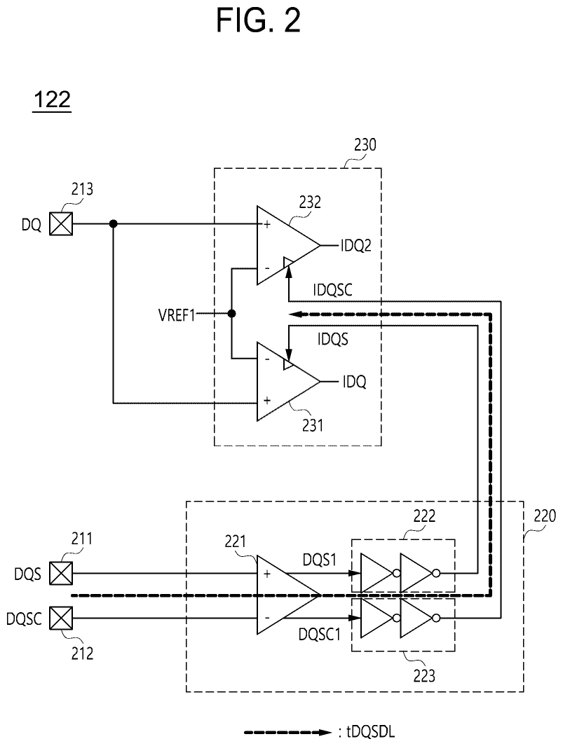

FIG. 2 is a block diagram illustrating the receiving circuit 122 of the semiconductor device 120 according to an embodiment of the present disclosure.

Referring to FIG. 2, the receiving circuit 122 may include a clock signal pad 211, a complementary clock signal pad 212, the clock path circuit 220, a data signal pad 213, and a data capture circuit 230.

The clock signal pad 211 may receive a clock signal DQS transmitted from the controller 110.

The complementary clock signal pad 212 may receive a complementary clock signal DQSC transmitted from the controller 110. The clock signal DQS and the complementary clock signal DQSC may be transmitted together. The complementary clock signal DQSC may have a 180-degree phase difference from the clock signal DQS.

The clock path circuit 220 may output the clock signal DQS transmitted from the clock signal pad 211 and the complementary clock signal DQSC transmitted from the complementary clock signal pad 212 as an internal clock signal IDQS and an internal complementary clock signal IDQSC, respectively. The clock path circuit 220 may output the internal clock signal IDQS and the internal complementary clock signal IDQSC by stabilizing the clock signal DQS and the complementary clock signal DQSC. The clock delay time tDQSDL may be the time taken from when the clock signal DQS is received through the clock signal pad 211 to when the clock signal DQS is input into the data capture circuit 230 as the internal clock signal IDQS after passing through the clock path circuit 220.

The clock path circuit 220 may include a clock comparison circuit 221, a first delay circuit 222, and a second delay circuit 223.

The clock comparison circuit 221 may output a result of comparing the clock signal DQS and the complementary clock signal DQSC as an intermediate clock signal DQS1 and an intermediate complementary clock signal DQSC1. The clock comparison circuit 221 may amplify a difference between the clock signal DQS and the complementary clock signal DQSC and output it as the intermediate clock signal DQS1 and the intermediate complementary clock signal DQSC1.

The first delay circuit 222 may delay the intermediate clock signal DQS1 and output it as the internal clock signal IDQS. The first delay circuit 222 may include an even number of inverters connected in series.

The second delay circuit 223 may delay the intermediate complementary clock signal DQSC1 and output it as the internal complementary clock signal IDQSC. The second delay circuit 223 may include an even number of inverters connected in series.

The data signal pad 213 may receive the data signal DQ transmitted from the controller 110. The data transmitted as the data signal DQ may be synchronized to the clock signal DQS.

The data capture circuit 230 may capture the data signal DQ transmitted from the data signal pad 213 in response to the internal clock signal IDQS and output an internal data IDQ, and may capture the data signal DQ transmitted from the data signal pad 213 in response to the internal complementary clock signal IDQSC and output a secondary internal data IDQ2.

The data capture circuit 230 may include a first comparison circuit 231 and a second comparison circuit 232.

The first comparison circuit 231 may output a result of comparing the data signal DQ transmitted from the data signal pad 213 with a first reference voltage VREF1 as the internal data IDQ in response to the internal clock signal IDQS.

The second comparison circuit 232 may output a result of comparing the data signal DQ transmitted from the data signal pad 213 with the first reference voltage VREF1 as the secondary internal data IDQ2 in response to the internal complementary clock signal IDQSC.

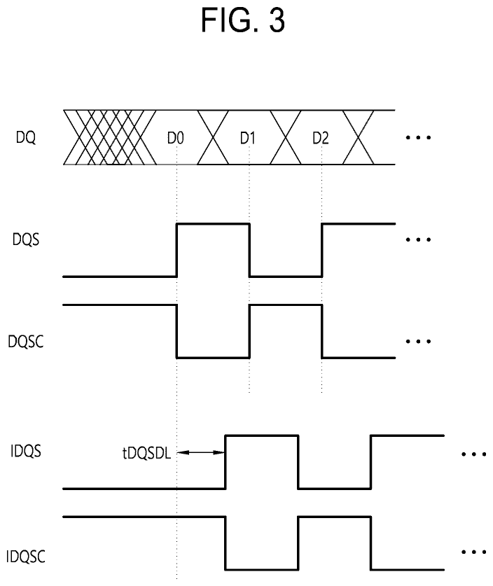

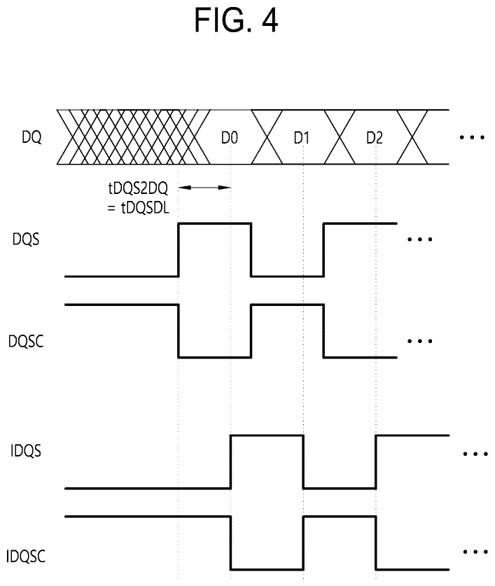

FIGS. 3 and 4 are timing diagrams to illustrate an operation of the receiving circuit 122 according to an embodiment of the present disclosure.

Referring to FIG. 3, the receiving circuit 122 may receive data D0, D1, D2 synchronized to the clock signal DQS and the complementary clock signal DQSC from the controller 110. For example, edges of the clock signal DQS and the complementary clock signal DQSC may be aligned at midpoints of valid windows of the data D0, D1, and D2.

In an embodiment, the clock signal DQS may be delayed by the clock delay time tDQSDL through the clock path circuit 220 and output as the internal clock signal IDQS. As a result, in an embodiment, edges of the internal clock signal IDQS may be offset from midpoints of valid windows of the data D0, D1, and D2, and the data D0, D1, and D2 might not be captured properly. In an embodiment, the complementary clock signal DQSC may be processed similarly to the clock signal DQS.

Referring to FIG. 4, the controller 110 may determine a clock-data time tDQS2DQ by performing a training operation during the initialization stage. The clock-data time tDQS2DQ may be the time at which the clock signal DQS must precede a midpoint of a valid window of data D0. The duration of the clock-data time tDQS2DQ may be substantially the same as the duration of the clock delay time tDQSDL. After performing the training operation, the controller 110 may transmit the clock signal DQS and the complementary clock signal DQSC that precede the midpoint of the valid window of data D0 by the clock-data time tDQS2DQ.

In an embodiment, the clock signal DQS may be delayed by the clock-delay time tDQSDL through the clock path circuit 220 and output as the internal clock signal IDQS. As a result, in an embodiment, the edges of the internal clock signal IDQS may be aligned with the midpoints of the valid windows of the data D0, D1, and D2, and the data D0, D1, and D2 may be captured normally based on the internal clock signal IDQS. In an embodiment, the complementary clock signal DQSC may be processed similarly to the clock signal DQS.

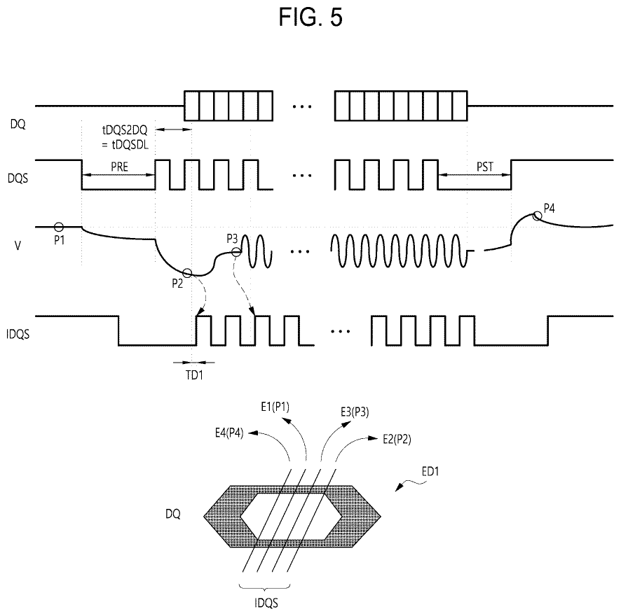

FIG. 5 is a diagram to illustrate a case where a change in voltage V causes a change in the clock delay time tDQSDL in the clock path circuit 220, according to an embodiment of the present disclosure.

Referring to FIG. 5, a change in voltage V supplied to the receiving circuit 122 while the data signal DQ and the clock signal DQS are input to the receiving circuit 122 is illustrated. The clock signal DQS may initially be at a predetermined level (e.g., a high level), and the voltage V may be kept at a voltage level P1. The clock signal DQS may be transmitted with a predetermined preamble PRE before transmitting the data signal DQ, which may cause the voltage V to drop slightly. After the preamble PRE, the clock signal DQS may be transmitted ahead of the data signal DQ by the clock-data time tDQS2DQ. As the clock signal DQS begins to be transmitted, the voltage V may temporarily drop to a voltage level P2. The voltage V may then recover slightly to a voltage level P3 through stabilizing operation of a voltage regulator of the semiconductor device 120. Voltage noise may be generated while the data signal DQ and clock signal DQS are transmitted. Then, as the transmission of the data signal DQ ends and the transmission of the postamble of the clock signal DQS ends, the voltage V may temporarily rise to a voltage level P4.

Referring to an eye diagram ED1 of the data signal DQ, when the voltage V of each of the voltage levels P1 to P4 is supplied to the receiving circuit 122, edges E1 to E4 of the internal clock signal IDQS may be positioned as shown. The edge E1 may be in an ideal position, i.e., at the midpoint of the valid window of the data signal DQ, when the voltage V at the voltage level P1 is reliably supplied to the receiving circuit 122. The edge E2 may be in a state of negative jitter due to a voltage drop to the voltage level P2 causing the clock delay time tDQSDL to increase by a time TD1. The edge E3 may be in a state of reduced negative jitter as the clock delay time tDQSDL, which increased by time TD1, decreases slightly as the voltage V slightly recovers to the voltage level P3. The edge E4 may be in a state of positive jitter, as the clock delay time tDQSDL decreases further due to the voltage V overshoot to the voltage level P4.

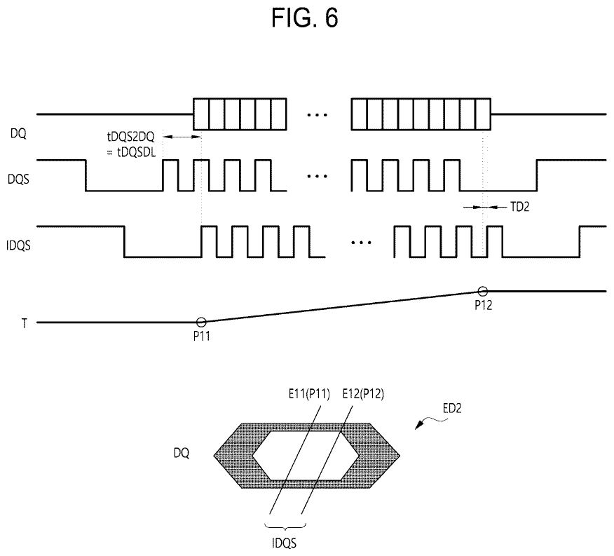

FIG. 6 is a diagram to illustrate a case where a change in internal temperature T causes a change in the clock delay time tDQSDL in the clock path circuit 220, according to an embodiment of the present disclosure.

Referring to FIG. 6, a change in the internal temperature T of the semiconductor device 120 is illustrated while the data signal DQ and the clock signal DQS are input to the receiving circuit 122. The internal temperature T may rise from a normal temperature P11 to a temperature P12 while the data signal DQ is transmitted.

Referring to an eye diagram ED2 of the data signal DQ, edges E11, E12 of the internal clock signal IDQS may be positioned as shown at the respective temperatures P11, P12. The edge E11 may be in an ideal position at the normal temperature P11, i.e., at the midpoint of the valid window of the data signal DQ. The edge E12 may be in a state where negative jitter has occurred, such that the clock delay time tDQSDL has increased by a time TD2 due to the increase in temperature P12.

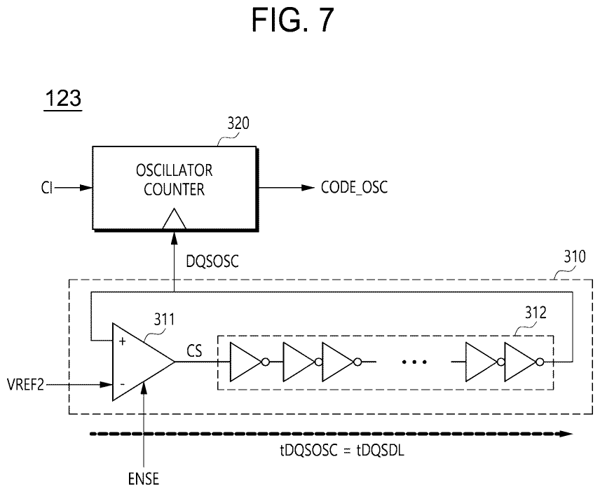

FIG. 7 is a block diagram illustrating the oscillator code generation circuit 123 of the semiconductor device 120 according to an embodiment of the present disclosure.

Referring to FIG. 7, the oscillator code generation circuit 123 may perform an oscillator operation of generating an oscillation signal DQSOSC to output an oscillator code CODE_OSC in response to an operation enable signal CI and an interval enable signal ENSE. The operation enable signal CI and the interval enable signal ENSE may be included in the second internal signal CTL2 of FIG. 1.

The oscillator code generation circuit 123 may include an oscillator 310 and an oscillator counter 320.

The oscillator 310 may output the oscillation signal DQSOSC in response to the interval enable signal ENSE. The oscillator 310 may include a comparison circuit 311 and an inverter chain 312.

The comparison circuit 311 may receive the oscillation signal DQSOSC at a non-inverting terminal and a second reference voltage VREF2 at an inverting terminal. The comparison circuit 311 may compare the oscillation signal DQSOSC and the second reference voltage VREF2 in response to the interval enable signal ENSE, and output a comparison result as a comparison signal CS.

The inverter chain 312 may invert the comparison signal CS to output a periodically oscillating oscillation signal DQSOSC. The inverter chain 312 may include an odd number of inverters connected in series. Each of the inverters may invert a received signal and output it.

The oscillator 310 may output the oscillation signal DQSOSC having a period N times the clock delay time tDQSDL, mimicking the clock path circuit 220 that delays the clock signal DQS by the clock delay time tDQSDL. The oscillation time tDQSOSC for the oscillation signal DQSOSC to cycle through the comparison circuit 311 and the inverter chain 312 may be substantially the same as the clock delay time tDQSDL of the clock path circuit 220.

The oscillator counter 320 may count predetermined edges (rising edges and/or falling edges) of the oscillation signal DQSOSC in response to the operation enable signal CI, and output a count value as the oscillator code CODE_OSC.

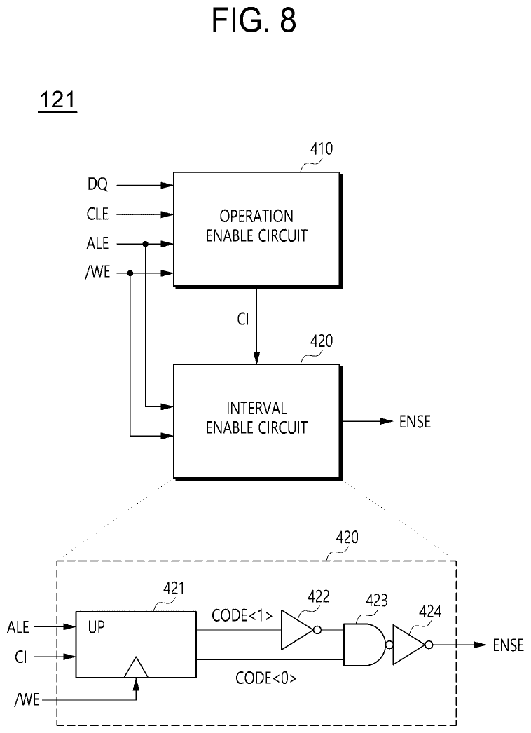

FIG. 8 is a block diagram illustrating the control circuit 121 according to an embodiment of the present disclosure.

Referring to FIG. 8, the control circuit 121 may receive the data signal DQ, the command latch enable signal CLE, the address latch enable signal ALE, and the write enable signal/WE, and may output the operation enable signal CI and the interval enable signal ENSE based on the data signal DQ, the command latch enable signal CLE, the address latch enable signal ALE, and the write enable signal/WE. The control circuit 121 may output the operation enable signal CI in an enabled state from the time an address at which the oscillator operation is to be performed is identified until the oscillator operation is terminated. In addition, the control circuit 121 may identify an oscillation interval during which the oscillation signal DQSOSC should be output through the address latch enable signal ALE, and output the interval enable signal ENSE in an enabled state during the oscillation interval. The data signal DQ, the command latch enable signal CLE, the address latch enable signal ALE, and the write enable signal/WE may be included in the external signal ECTL of FIG. 1. As mentioned above, with regard to FIG. 1, the external signal ECTL may also include the clock signal DQS. Here in FIG. 8, we are focused on the data signal DQ, the command latch enable signal CLE, the address latch enable signal ALE, and the write enable signal/WE that is included in the external signal ECTL.

The control circuit 121 may include an operation enable circuit 410 and an interval enable circuit 420.

The operation enable circuit 410 may receive the data signal DQ, the command latch enable signal CLE, the address latch enable signal ALE, and the write enable signal/WE, and may output the operation enable signal CI based on the data signal DQ, the command latch enable signal CLE, the address latch enable signal ALE, and the write enable signal/WE.

Specifically, the operation enable circuit 410 may identify an oscillator operation command from the data signal DQ based on the command latch enable signal CLE. The operation enable circuit 410 may identify at least one address in the data signal DQ based on the address latch enable signal ALE. The operation enable circuit 410 may capture the oscillator operation command and the at least one address in the data signal DQ in response to the write enable signal/WE, respectively. In response to receiving the oscillator operation command and the at least one address, the operation enable circuit 410 may output the operation enable signal CI in an enabled state.

While the operation enable signal CI is in an enabled state, the operation enable circuit 410 may identify an oscillation start signal in the data signal DQ based on the address latch enable signal ALE. And, based on the address latch enable signal ALE, the operation enable circuit 410 may identify an oscillation end signal in the data signal DQ. The operation enable circuit 410 may capture the oscillation start signal and the oscillation end signal in response to the write enable signal/WE, respectively. In response to receiving the oscillation start signal and the oscillation end signal, the operation enable circuit 410 may output the operation enable signal CI in a disabled state.

The interval enable circuit 420 may receive the write enable signal/WE, the address latch enable signal ALE, and the operation enable signal CI, and may output the interval enable signal ENSE based on the write enable signal/WE, the address latch enable signal ALE, and the operation enable signal CI. The interval enable circuit 420 may output the interval enable signal ENSE that is in an enabled state in the oscillation interval and in a disabled state in non-oscillation interval. The oscillation interval may be a period from receipt of the oscillation start signal until receipt of the oscillation end signal.

The interval enable circuit 420 may include a counter 421, a first inverter 422, a first NAND gate 423, and a second inverter 424.

The counter 421 may receive the write enable signal/WE, the address latch enable signal ALE, and the operation enable signal CI, and may output an interval code CODE<1:0> based on the write enable signal/WE, the address latch enable signal ALE, and the operation enable signal CI. Specifically, the counter 421 may output a reset interval code CODE<1:0> while the operation enable signal CI is initially in a disabled state, and may begin a counting operation in response to the operation enable signal CI transitioning from a disabled state to an enabled state. The counter 421 may count the address latch enable signal ALE in response to the write enable signal/WE and output a count value as the interval code CODE<1:0>.

Specifically, the counter 421 may output a predetermined interval code CODE<1:0> in the oscillation interval. Because the oscillation start signal and the oscillation end signal are transmitted together with the address latch enable signal ALE, the counter 421 may determine the start and end of the oscillation interval by counting the address latch enable signal ALE while the operation enable signal CI is in an enabled state, respectively. For example, the counter 421 may determine the start of the oscillation interval to be when the first address latch enable signal ALE is received while the operation enable signal CI is in an enabled state. And the counter 421 may determine the end of the oscillation interval to be when the second address latch enable signal ALE is received while the operation enable signal CI is in an enabled state.

The first inverter 422 may receive the most significant bit CODE<1> of the interval code, and may invert and output the received value. The first NAND gate 423 may receive an output of the first inverter 422 and the least significant bit CODE<0> of the interval code, may perform a NAND operation on the output of the first inverter 422 and the least significant bit CODE<0> of the interval code, and may output a result of the NAND operation. The second inverter 424 may receive an output of the first NAND gate 423, invert a received value, and output it as the interval enable signal ENSE.

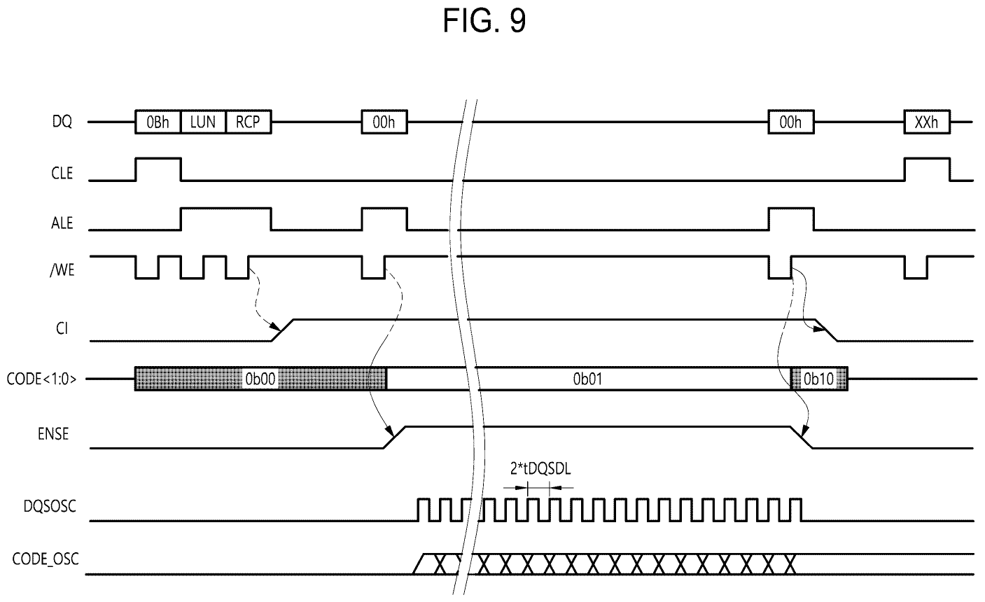

FIG. 9 is a timing diagram to illustrate how the semiconductor device 120 performs an oscillator operation according to an embodiment of the present disclosure.

Referring to FIG. 9, an oscillator operation command 0Bh, a first address LUN, a second address RCP, an oscillation start signal 00h, and an oscillation end signal 00h may be received as the data signal DQ from the controller 110. The oscillator operation command 0Bh may be for instructing to perform an oscillator operation. The oscillator operation command 0Bh may be transmitted with the command latch enable signal CLE. The first address LUN may be used to designate a semiconductor chip on which the oscillator operation is to be performed. The second address RCP may be used to indicate whether the oscillator operation is to be performed on a single semiconductor die or on all semiconductor dies. The first address LUN and second address RCP may be transmitted together with the address latch enable signal ALE. In an embodiment, at least one address following the oscillator operation command 0Bh may be transmitted according to a regulation other than the first address LUN and the second address RCP. The time from the second address RCP to the oscillation start signal 00h may be a predetermined time required for the semiconductor device 120 to prepare for the oscillator operation. A command XXh for next operation may be input after a predetermined time from the oscillation end signal 00h. The values of the oscillator operation command 0Bh, the oscillation start signal 00h, and the oscillation end signal 00h may be an example.

The operation enable circuit 410 may capture the oscillator operation command 0Bh in response to a first rising edge of the write enable signal/WE, capture the first address LUN in response to a second rising edge of the write enable signal/WE, and capture the second address RCP in response to a third rising edge of the write enable signal/WE. The operation enable signal CI may be enabled in response to receiving the oscillator operation command 0Bh and both the first and second addresses LUN, RCP.

While the operation enable signal CI is in an enabled state, the operation enable circuit 410 may capture the oscillation start signal 00h in response to a fourth rising edge of the write enable signal/WE and capture the oscillation end signal 00h in response to a fifth rising edge of the write enable signal/WE. The operation enable signal CI may be disabled in response to receiving the oscillation start signal 00h and the oscillation end signal 00h.

The interval code CODE<1:0> may be output as a reset interval code (e.g., ‘00’) while the operation enable signal CI is initially in a disabled state. The counter 421 may determine that the start of the oscillation interval is when a first address latch enable signal ALE is received while the operation enable signal CI is in an enabled state. And the counter 421 may determine that the end of the oscillation interval is when the second address latch enable signal ALE is received while the operation enable signal CI is in an enabled state. Therefore, the interval code CODE<1:0> may be output as ‘00’ before the start of the oscillation interval, ‘01’ from the start of the oscillation interval to the end of the oscillation interval, and ‘10’ after the end of the oscillation interval.

The interval enable signal ENSE may be enabled during the oscillation interval between the oscillation start signal 00h and the oscillation end signal 00h in response to the interval code CODE<1:0> ‘01’.

The oscillation signal DQSOSC may be output while the interval enable signal ENSE is in an enabled state. The aforementioned N may be, for example, ‘2’, and the oscillation signal DQSOSC may have a period of twice the clock delay time tDQSDL.

The oscillator counter 320 may count the oscillation signal DQSOSC and output a count value as the oscillator code CODE_OSC.

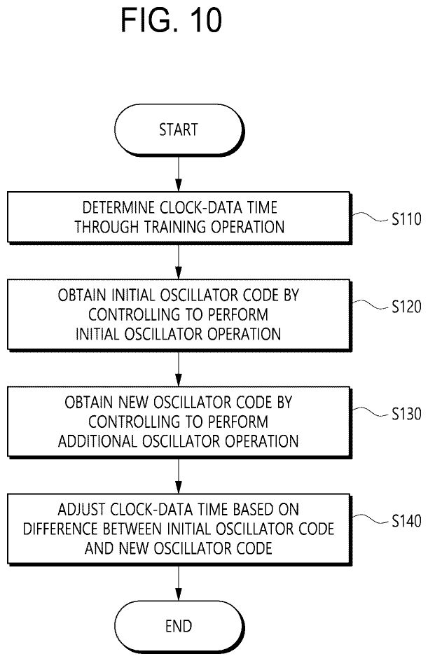

FIG. 10 is a flowchart illustrating an operating method of the semiconductor system 100 according to an embodiment of the present disclosure.

In operation S110, the controller 110 may determine the clock-data time tDQS2DQ through a training operation for the semiconductor device 120. The training operation may be performed during the initialization stage after power-on. The clock-data time tDQS2DQ may be a delay time between the clock signal DQS and the data transmitted by the controller 110 to the semiconductor device 120.

In operation S120, the controller 110 may obtain the initial oscillator code by controlling the semiconductor device 120 to perform an initial oscillator operation. The initial oscillator operation may be performed after the training operation during the initialization stage. The initial oscillator operation may include generating the oscillation signal DQSOSC having a period of N times the clock delay time tDQSDL and generating the initial oscillator code by counting the oscillation signal DQSOSC. The clock delay time tDQSDL may be a time that the clock signal DQS received from the controller 110 is delayed to the internal clock signal IDQS.

In operation S130, the controller 110 may obtain a new oscillator code by controlling the semiconductor device 120 to perform an additional oscillator operation. The additional oscillator operation may include generating the oscillation signal DQSOSC having a period of N times the clock delay time tDQSDL and counting the oscillation signal DQSOSC to generate the new oscillator code. In an embodiment, before the operation S130, the controller 110 may determine whether the clock-data time tDQS2DQ needs to be adjusted. When it is determined that the clock-data time tDQS2DQ needs to be adjusted, the procedure may proceed to the operation S130.

In operation S140, the controller 110 may adjust the clock-data time tDQS2DQ based on a difference between the initial oscillator code and the new oscillator code. The controller 110 may apply a predetermined conversion algorithm to the difference between the initial oscillator code and the new oscillator code to determine an amount of adjustment of the clock-data time tDQS2DQ.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that the meaning and scope of the claims and all changes or modified forms derived from the equivalent concept thereof are included in the scope of the present disclosure.

What is claimed is:

1. A semiconductor device, comprising:
a receiving circuit configured to receive a clock signal and a data signal including data, configured to delay the clock signal by a clock delay time to generate an internal clock signal, and configured to capture the data using the internal clock signal;
an oscillator code generation circuit configured to generate an oscillation signal having a period of N times the clock delay time, wherein N is a positive integer, and configured to generate an oscillator code based on the oscillation signal; and
a control circuit configured to control the oscillator code generation circuit in response to at least one external signal, during an initialization stage after power-on.

2. The semiconductor device of claim 1, wherein the oscillator code generation circuit comprises:
an oscillator configured to output the oscillation signal in response to an interval enable signal received from the control circuit; and
an oscillator counter configured to output the oscillator code by counting the oscillation signal in response to an operation enable signal received from the control circuit.

3. The semiconductor device of claim 2, wherein the control circuit includes an operation enable circuit configured to enable the operation enable signal in response to sequentially receiving an oscillator operation command and at least one address in the data signal included in the at least one external signal, and configured to disable the operation enable signal in response to sequentially receiving an oscillation start signal and an oscillation end signal as the data signal.

4. The semiconductor device of claim 3, wherein the operation enable circuit is configured to output the operation enable signal in response to the data signal, a command latch enable signal, an address latch enable signal, and a write enable signal included in the at least one external signal.

5. The semiconductor device of claim 3, wherein the control circuit further comprises an interval enable circuit configured to output the interval enable signal in an enabled state during an oscillation interval from receipt of the oscillation start signal until receipt of the oscillation end signal.

6. The semiconductor device of claim 5, wherein the interval enable circuit is configured to output the interval enable signal in response to a write enable signal and an address latch enable signal included in the at least one external signal, and the operation enable signal.

7. The semiconductor device of claim 6, wherein the interval enable circuit includes a counter configured to output an interval code corresponding to the oscillation interval by counting the address latch enable signal while the operation enable signal is enabled.

8. The semiconductor device of claim 6, wherein the address latch enable signal is enabled while the oscillation start signal is received by the control circuit and while the oscillation end signal is received by the control circuit.

9. A semiconductor system, comprising:
a semiconductor device configured to process a clock signal and data based on a clock delay time; and
a controller configured, during an initialization stage after power-on, to determine a clock-data time corresponding to the clock delay time by a training operation on the clock signal and the data, and configured to obtain a first oscillator code by controlling the semiconductor device to perform a first oscillator operation,
wherein the semiconductor device is configured to, in the first oscillator operation, generate an oscillation signal having a period of N times the clock delay time, wherein N is a positive integer, and configured to generate the first oscillator code based on the oscillation signal.

10. The semiconductor system of claim 9, wherein the semiconductor device is configured to count the oscillation signal, and configured to generate the first oscillator code based on a count value.

11. The semiconductor system of claim 9, wherein the semiconductor device is configured to delay the clock signal by the clock delay time to generate an internal clock signal, and configured to capture the data based on the internal clock signal.

12. The semiconductor system of claim 9, wherein the clock-data time is a delay time between the clock signal and the data transmitted by the controller to the semiconductor device.

13. The semiconductor system of claim 9, wherein the controller is configured to obtain a second oscillator code by controlling the semiconductor device to perform a second oscillator operation in response to determining that an adjustment of the clock-data time is required, and configured to adjust the clock-data time based on a difference between the first oscillator code and the second oscillator code.

14. The semiconductor system of claim 13, wherein the controller is configured to determine that the adjustment of the clock-data time is required when the controller determines that a timing error has occurred.

15. An operating method of a semiconductor system, the method comprising:
determining, by a controller, a clock-data time corresponding to a clock delay time of a semiconductor device through a training operation;
obtaining, by the controller, a first oscillator code by controlling the semiconductor device to perform a first oscillator operation;
obtaining, by the controller, a second oscillator code by controlling the semiconductor device to perform a second oscillator operation; and
adjusting, by the controller, the clock-data time based on a difference between the first oscillator code and the second oscillator code.

16. The method of claim 15, wherein the training operation and the first oscillator operation are performed during an initialization stage after power-on.

17. The method of claim 15, wherein the first oscillator operation comprises:
generating an oscillation signal having a period of N times the clock delay time, wherein N is a positive integer; and
generating the first oscillator code by counting the oscillation signal.

18. The method of claim 15, wherein the clock delay time is a time for delaying a clock signal received from the controller to generate an internal clock signal used by the semiconductor device to capture data received from the controller.

19. The method of claim 15, wherein the clock-data time is a delay time between a clock signal and data transmitted by the controller to the semiconductor device.

20. The method of claim 15, further comprising, before obtaining the second oscillator code, determining, by the controller, whether the clock-data time needs to be adjusted.
